(19) United States
(12) Patent Application Publication
(10) Pub. No.: US 2006/0226912 A1
(43) Pub. Date: Oct. 12, 2006

(54) Apparatus and method for limiting voltage surge at amplifier start up

(76) Inventors: Edwin Suryahusada, Richardson, TX (US); Patrick Muggler, Dallas, TX (US)

Correspondence Address: TEXAS INSTRUMENTS INCORPORATED, P O BOX 655474, M/S 3999, DALLAS, TX, 75265, US

(21) Appl. No.: 11/092,959

(22) Filed: Mar. 29, 2005

(51) Int. Cl. H03F 3/04

(52) U.S. Cl. 330/302

(57) ABSTRACT

An apparatus for reducing voltage surge while powering up an amplifier device, the amplifier device charging an input capacitance in at least one input line during the powering up, the charging being subject to a time constant established by the input capacitance in cooperation with an input resistance in the at least one input line, includes: a resistive load switchingly coupled with at least a portion of the input resistance in the at least one input line. The switchingly coupling is effected during at least a portion of the powering up.

### BACKGROUND OF THE INVENTION

The present invention is directed to input stages of amplifier devices. The present invention may be particularly advantageously used with an input stage for an audio amplifier device. The present invention will be described in terms of an audio amplifier device solely in an illustrative manner with the understanding that the invention is useful with other amplifier devices as well.

When an amplifier is powered up, or turned on, there is often a voltage surge that occurs. The voltage surge is commonly manifested as an audible “pop” or “click” that is a significant annoyance to users. The pop/click may be more than a mere annoyance. If the voltage surge is large enough the pop/click may loud enough to damage speakers coupled with the amplifier device. Speaker coils may be damaged permanently.

There is a need for an apparatus and method for limiting voltage surge at amplifier start up to avoid damage to the amplifier or damage to equipment coupled with the amplifier.

### SUMMARY OF THE INVENTION

An apparatus for reducing voltage surge while powering up an amplifier device, the amplifier device charging an input capacitance in at least one input line during the powering up, the charging being subject to a time constant established by the input capacitance in cooperation with an input resistance in the at least one input line, includes: a resistive load switchingly coupled with at least a portion of the input resistance in the at least one input line. The switchingly coupling is effected during at least a portion of the powering up.

A method for reducing voltage surge while powering up an amplifier device, the amplifier device charging an input capacitance in at least one input line during the powering up, the charging being subject to a time constant established by the input capacitance in cooperation with an input resistance in the at least one input line, includes the steps of: (a) providing a resistive load; and (b) switchingly coupling the resistive load with at least a portion of the input resistance in the at least one input line. The switchingly coupling is effected during at least a portion of the powering up.

It is, therefore, an object of the present invention to provide an apparatus and method for limiting voltage surge at amplifier start up to avoid damage to the amplifier or damage to equipment coupled with the amplifier.

Further objects and features of the present invention will be apparent from the following specification and claims when considered in connection with the accompanying drawings, in which like elements are labeled using like reference numerals in the various figures, illustrating the preferred embodiments of the invention.

### BRIEF DESCRIPTION OF THE DRAWINGS

FIG. 1 is an electrical schematic diagram of a prior art input circuit for an amplifier.

FIG. 2 is a graphic representation of selected signals in the prior art input circuit illustrated in FIG. 1.

FIG. 3 is an electrical schematic diagram of an input circuit for an amplifier configured according to the present invention.

FIG. 4 is a graphic representation of selected signals in the input circuit illustrated in FIG. 3.

### DETAILED DESCRIPTION OF THE PREFERRED EMBODIMENT

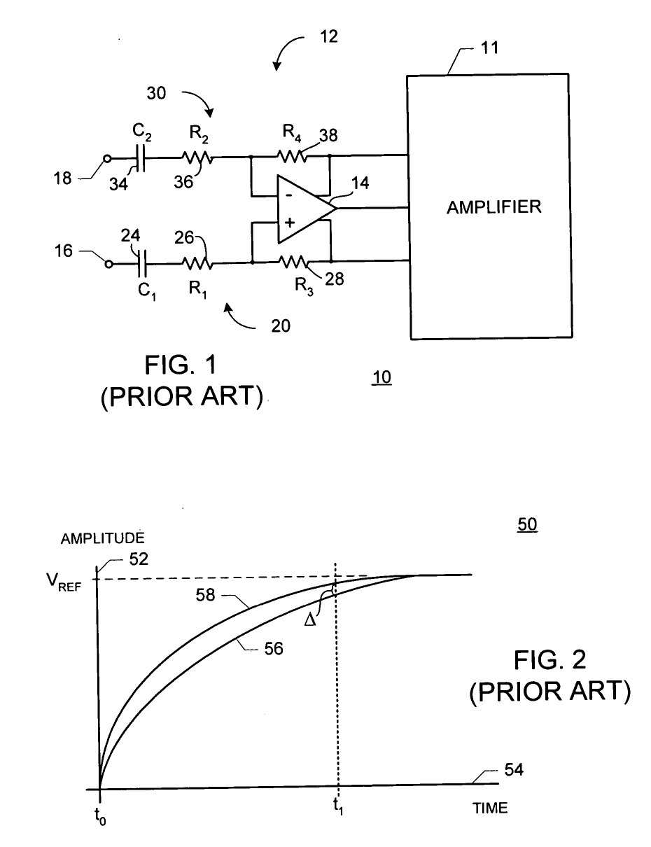

FIG. 1 is an electrical schematic diagram of a prior art input circuit for an amplifier. In FIG. 1, an amplifier system 10 includes an amplifier device 111 and an input section 12. Input section 12 includes a preamplifier unit 14 coupled with amplifier device 11 and coupled with input loci 16, 18 for receiving input signals.

Preamplifier unit 14 receives first input signals via a first input network 20 from input locus 16. First input network 20 includes a capacitor 24 and a resistor 26. Preamplifier unit 14 is biased with respect to first input network 20 by a resistor 28. Capacitor 24 has a value C₁. Resistor 26 has a value R₁. Resistor 28 has a value R₃.

Preamplifier unit 14 receives second input signals via a second input network 30 from input locus 18. Second input network 30 includes a capacitor 34 and a resistor 36. Preamplifier unit 14 is biased with respect to second input network 30 by a resistor 38. Capacitor 34 has a value C₂. Resistor 36 has a value R₂. Resistor 38 has a value R₄.

Amplifier system 10 is illustratively described herein as a fully differential amplifier system. The present invention is equally useful with a non-differential, single-ended amplifier system having only one input locus 16 or 18.

FIG. 2 is a graphic representation of selected signals in the prior art input circuit illustrated in FIG. 1. In FIG. 2, a graphic plot 50 is presented with respect to a vertical axis 52 representing signal amplitude, such as voltage amplitude and with respect to a horizontal axis 54 representing time. A first curve 56 represents charge on first capacitor 24 (FIG. 1). A second curve 58 represents charge on second capacitor 34 (FIG. 1). Times t₀, t₁ are indicated on axis 54. Time t₀ represents the time at which amplifier system 10 is initially powered up. Time t₁ represents the time at which amplifier device 11 is turned on. During the interval t₀-t₁, only input section 12 is turned on and amplifier device 11 is not yet powered. Preamplifier unit 14 charges capacitors 24, 34 to a voltage reference V_{REF} which sets the common-mode voltage for amplifier device 11 during interval t₀-t₁. Certain biases and references for operating amplifier device 11 are also permitted to settle during interval t₀-t₁ before amplifier device 11 is turned on.

Time t₁ for turning on amplifier device 11 is commonly established according to standards in effect for a given product in which amplifier system 10 is employed (not shown in FIG. 1). As a consequence a difference in charge level often exists between capacitors 24, 34, as indicated by difference between curves 56, 58 at time t₁ in FIG. 2. It is difference between charge levels of capacitors 24, 34 that causes a voltage surge into amplifier device 11 when amplifier device 11 is turned on at time t₁.

It is desired that first input network 20 and second input network 30 are substantially the same. In the interest of simplifying explaining the present invention and avoiding unnecessary prolixity, only first input network 20 will be described with the understanding that the principles described apply equally to second input network 30.

While charging capacitor 24 first input network 20 represents a low pass filter having an RC (resistive-capacitive) time constant T₁:
T₁=(R₁+R₃)·C₁ [1]

By way of example and not by way of limitation, if amplifier system 10 were embodied in an audio amplifier typical values for C₁, R₁, R₃ yield a time constant T₁ in a range from 157 msec to 863 msec. Time required for capacitors 24, 34 to settle to within 0.1% of their final values requires approximately 5-7 time constants. Such a delay in turning on amplifier device 11 after powering up preamplifier unit 12 is regarded as unsatisfactory in many of today's products. By way of further example and not by way of limitation, products such as personal digital assistant (PDA) devices or cellular phones frequently enter a “sleep” mode to conserve battery power. Having to wait for a second or more to reenter an active mode from such a sleep mode is irritating to a user.

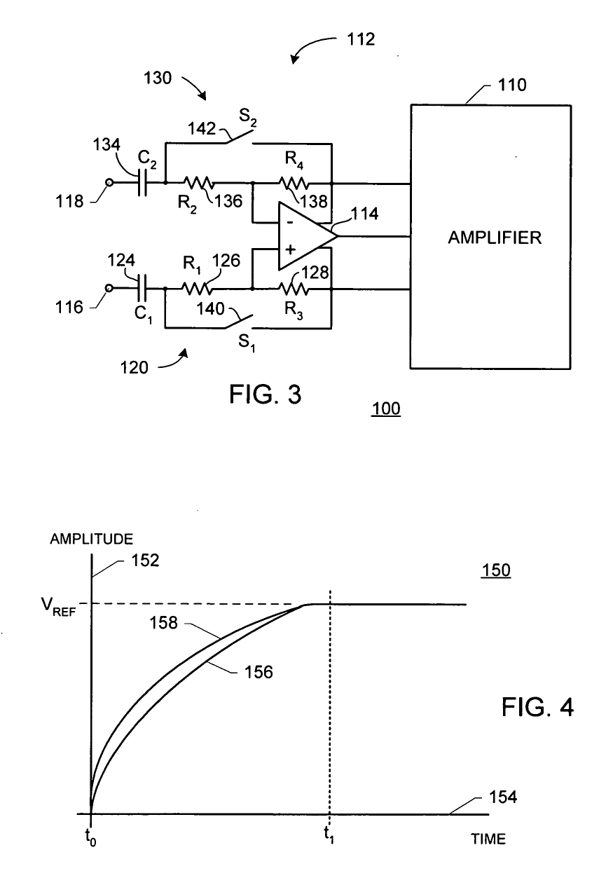

FIG. 3 is an electrical schematic diagram of an input circuit for an amplifier configured according to the present invention. In FIG. 3, an amplifier system 100 includes an amplifier device 110 and an input section 112. Input section 112 includes a preamplifier unit 114 coupled with amplifier device 110 and coupled with input loci 116, 118 for receiving input signals.

Preamplifier unit 114 receives first input signals via a first input network 120 from input locus 116. First input network 120 includes a capacitor 124 and a resistor 126. Preamplifier unit 114 is biased with respect to first input network 120 by a resistor 128. Capacitor 124 has a value C₁. Resistor 126 has a value R₁. Resistor 128 has a value R₃. First input network 120 also includes a switch 140 coupled in parallel with series-connected resistors 126, 128. Switch 140 has a resistance R_{S1} when switch 140 is closed.

Preamplifier unit 114 receives second input signals via a second input network 130 from input locus 118. Second input network 130 includes a capacitor 134 and a resistor 136. Preamplifier unit 114 is biased with respect to second input network 130 by a resistor 138. Capacitor 134 has a value C₂. Resistor 136 has a value R₂. Resistor 138 has a value R₄. Second input network 130 also includes a switch 142 coupled in parallel with series-connected resistors 136, 138. Switch 142 has a resistance R_{S2} when switch 142 is closed.

Amplifier system 100 is illustratively described herein as a fully differential amplifier system. The present invention is equally useful with a non-differential amplifier system having only one input locus 116 or 118.

FIG. 4 is a graphic representation of selected signals in the input circuit illustrated in FIG. 3. In FIG. 4, a graphic plot 150 is presented with respect to a vertical axis 152 representing signal amplitude, such as voltage amplitude and with respect to a horizontal axis 154 representing time. A first curve 156 represents charge on first capacitor 124 (FIG. 3). A second curve 158 represents charge on second capacitor 134 (FIG. 3). Times t₀, t₁ are indicated on axis 154. Time t₀ represents the time at which amplifier system 100 is initially powered up. Time t₁ represents the time at which amplifier device 110 is turned on. During the interval t₀-t₁, only input section 112 is turned on and amplifier device 111 is not yet powered. Preamplifier unit 114 charges capacitors 124, 134 to a voltage reference V_{REF} which sets the common-mode voltage for amplifier device 110 during interval t₀-t₁. Certain biases and references for operating amplifier device 110 are also permitted to settle during interval t₀-t₁ before amplifier device 110 is turned on. During interval t₀-t₁ switches 140, 142 are closed.

It is desired that first input network 120 and second input network 130 are substantially the same. In the interest of simplifying explaining the present invention and avoiding unnecessary prolixity, only first input network 120 will be described with the understanding that the principles described apply equally to second input network 130.

While charging capacitor 124 first input network 120 represents a low pass filter having an RC (resistive-capacitive) time constant T₂:
T₂=[(R₁+R₃)∥RS1]·C₁ [2]

The preferred embodiment of switch 140 is an FET (field effect transistor) so that resistance R_{S1} is established substantially as the drain-to-source resistance of switch 140. As a consequence,
R_{S1}<<(R₁+R₃) [3]

So that time constant T₂ is substantially reduced to
T₂=RS1·C₁ [4]

Time constant T₂ is thus substantially less than time constant T₁ (FIG. 1) for a comparable product. In practical terms, this means that capacitors 124, 134 will charge much more quickly than capacitors 24, 34 (FIG. 1) in a comparable product so that both of capacitors 124, 134 are similarly charged by time t_{1.} There is no charge differential between capacitors 124, 134 at time t₁ when amplifier device 110 is turned on so there is no voltage surge passed through amplifier device 110 and manifested as a pop/click or other signal anomaly.

In operation, switches 140, 142 are preferably only closed during interval t₀-t₁ and are opened no later than time t₁ when amplifier device 110 is turned on. This may be effected using a timed interval during which switches 140, 142 are turned on following powering up of preamplifier section 114, or by using another control arrangement (not shown in FIG. 2).

The present invention permits a very fast powering up of an amplifier device. By assuring that input capacitors (e.g., capacitors 124, 134) are substantially fully charged before turning on an amplifier device (e.g., amplifier device 110), a designer may employ less stringently toleranced capacitors in an amplifier design and thereby use less expensive components in a design using the present invention. There is less need to closely match capacitors to reduce charge difference when turning on an amplifier device because the present invention assures that the charge difference is substantially eliminated by the time the amplifier device is turned on.

It is to be understood that, while the detailed drawings and specific examples given describe preferred embodiments of the invention, they are for the purpose of illustration only, that the apparatus and method of the invention are not limited to the precise details and conditions disclosed and that various changes may be made therein without departing from the spirit of the invention which is defined by the following claims:

I claim:

1. An apparatus for reducing voltage surge while powering up an amplifier device; said amplifier device charging an input capacitance in at least one input line during said powering up; said charging being subject to a time constant established by said input capacitance in cooperation with an input resistance in said at least one input line; the apparatus comprising: a switched resistive load switchingly coupled with at least a portion of said input resistance in said at least one input line; said switchingly coupling being effected during at least a portion of said powering up.

2. An apparatus for reducing voltage surge while powering up an amplifier device as recited in claim 1 wherein said switched resistive load is coupled in parallel with at least a portion of said input resistance in said at least one input line.

3. An apparatus for reducing voltage surge while powering up an amplifier device as recited in claim 1 wherein said at least one input line is two input lines; said switched resistive load being substantially equal in each input line of said two input lines.

4. An apparatus for reducing voltage surge while powering up an amplifier device as recited in claim 1 wherein said switched resistive load is a switch having an inherent resistance when closed.

5. An apparatus for reducing voltage surge while powering up an amplifier device as recited in claim 1 wherein said switchingly coupling is effected for a predetermined time interval during said powering up.

6. An apparatus for reducing voltage surge while powering up an amplifier device as recited in claim 2 wherein said at least one input line is two input lines; said switched resistive load being substantially equal in each input line of said two input lines.

7. An apparatus for reducing voltage surge while powering up an amplifier device as recited in claim 6 wherein said switched resistive load is a switch having an inherent resistance when closed.

8. An apparatus for reducing voltage surge while powering up an amplifier device as recited in claim 7 wherein said switchingly coupling is effected for a predetermined time interval during said powering up.

9. An apparatus for reducing time for charging an input capacitance in at least one input line when powering up an amplifier device; said charging being subject to a time constant established by said input capacitance in cooperation with a resistance in said at least one input line; the apparatus comprising: a resistive load switchingly coupled with at least a portion of said resistance in said at least one input line; said switchingly coupling being effected during at least a portion of time said powering up occurs.

10. An apparatus for reducing time for charging an input capacitance in at least one input line when powering up of an amplifier device as recited in claim 9 wherein said resistive load is coupled in parallel with at least a portion of said resistance in said at least one input line.

11. An apparatus for reducing time for charging an input capacitance in at least one input line when powering up of an amplifier device as recited in claim 9 wherein said at least one input line is two input lines; said resistive load being substantially equal in each input line of said two input lines.

12. An apparatus for reducing time for charging an input capacitance in at least one input line when powering up of an amplifier device as recited in claim 9 wherein said resistive load is a switch having an inherent resistance when closed.

13. An apparatus for reducing time for charging an input capacitance in at least one input line when powering up of an amplifier device as recited in claim 9 wherein said switchingly coupling is effected for a predetermined time interval during said powering up.

14. An apparatus for reducing time for charging an input capacitance in at least one input line when powering up of an amplifier device as recited in claim 10 wherein said at least one input line is two input lines; said resistive load being substantially equal in each input line of said two input lines.

15. An apparatus for reducing time for charging an input capacitance in at least one input line when powering up of an amplifier device as recited in claim 14 wherein said resistive load is a switch having an inherent resistance when closed.

16. An apparatus for reducing time for charging an input capacitance in at least one input line when powering up of an amplifier device as recited in claim 15 wherein said switchingly coupling is effected for a predetermined time interval during said powering up.

17. A method for reducing voltage surge while powering up an amplifier device; said amplifier device charging an input capacitance in at least one input line during said powering up; said charging being subject to a time constant established by said input capacitance in cooperation with an input resistance in said at least one input line; the method comprising the steps of:
(a) providing a resistive load; and
(b) switchingly coupling said resistive load with at least a portion of said input resistance in said at least one input line; said switchingly coupling being effected during at least a portion of said powering up.

18. A method for reducing voltage surge while powering up an amplifier device as recited in claim 17 wherein said resistive load is coupled in parallel with at least a portion of said input resistance in said at least one input line.

19. A method for reducing voltage surge while powering up an amplifier device as recited in claim 17 wherein said at least one input line is two input lines; said resistive load being substantially equal in each input line of said two input lines.

20. A method for reducing voltage surge while powering up an amplifier device as recited in claim 17 wherein said resistive load is a switch having an inherent resistance when closed.
